(19) United States
(12) Patent Application Publication
(10) Pub. No.: US 2026/0358425 A1
(43) Pub. Date: Nov. 12, 2026

(54) INTELLIGENT ELECTROLYTE PREDICTION SYSTEM FOR PREDICTING REDOX POTENTIALS OF ELECTROLYTE MOLECULES

(71) Applicant: Hong Kong Applied Science and Technology Research Institute Company Limited, Hong Kong (HK)

(72) Inventors: Cuili ZHANG, Hong Kong (HK); Lang WANG, Hong Kong (HK); Shengbo LU, Hong Kong (HK); Chenmin LIU, Hong Kong (HK); Deshuai YANG, Hong Kong (HK); Jun FAN, Hong Kong (HK)

(21) Appl. No.: 19/670,049

(22) Filed: May 7, 2026

Related U.S. Application Data
(60) Provisional application No. 63/802,653, filed on May 9, 2025.

(51) Int. Cl. G01R 31/367; G01R 31/36; G01R 31/378; H01M 10/0525

(52) U.S. Cl. CPC G01R 31/367; G01R 31/3648; G01R 31/378; H01M 10/0525

(57) ABSTRACT

A redox potential prediction system for evaluating and screening candidate electrolyte molecules under lithium-ion-coordinated condition and under a non-lithium-ion-coordinated condition for rechargeable lithium-ion batteries is provided. The system includes a candidate electrolyte collection module, a first-principles computation module, a feature extraction module, a feature engineering module, a model training module, a model evaluation module, an interpretability analysis module, and a redox prediction output module. Candidate electrolyte molecules are collected and subjected to first-principles computation to generate redox-potential-related computational data. Electronic features and structural features are extracted from the computational data and processed to generate a feature set for machine-learning-based prediction. One or more prediction models are trained and evaluated to generate prediction-related data and model-evaluation-related data. Interpretability analysis is performed to determine contributions of molecular descriptors to oxidation potential prediction and reduction potential prediction. The system outputs oxidation-potential prediction results, reduction-potential prediction results, or both, for the candidate electrolyte molecules.

### CROSS-REFERENCE TO RELEVANT APPLICATIONS

The present application claims priority from a U.S. provisional patent application Ser. No. 63/802,653 filed May 9, 2025, and the disclosure of which are incorporated by reference in their entirety.

### TECHNICAL FIELD

The present invention generally relates to battery technology, machine learning, and artificial intelligence for science. More particularly, the present invention relates to a redox potential prediction framework for electrolyte molecules in rechargeable batteries, in which first-principles calculation with lithium-ion coordination effects and machine learning are jointly used to predict oxidation and reduction potentials of electrolyte molecules.

### BACKGROUND

Conventionally, electrochemical stability of electrolyte molecules has been evaluated through experimental approaches such as cyclic voltammetry and through quantum mechanical calculation approaches such as thermodynamic-cycle-based methods. However, experimental approaches may have limited reliability in the presence of reversible redox processes, thereby making it difficult to accurately assess an electrochemical stability window of a candidate electrolyte molecule. In addition, quantum mechanical approaches, such as Born-Haber thermodynamic cycle calculations, generally require substantial computational resources when applied to a large number of candidate molecules, and such approaches may not adequately reflect lithium-ion coordination effects that are present in battery environments.

Furthermore, although machine learning techniques have been introduced for molecular property prediction, existing machine learning approaches are generally not specifically configured for lithium-ion-coordinated electrolyte systems, often rely on datasets having insufficient chemical diversity, and typically provide limited explanation regarding which molecular factors drive redox behavior. As a result, existing techniques are often inadequate for accurately predicting oxidation potential and reduction potential under lithium-ion-rich electrode environments, which in turn limits efficient design and screening of electrolyte molecules for rechargeable batteries, particularly for high-voltage cathode applications.

Therefore, there is a need for an improved method and system that can effectively predict redox potentials of electrolyte molecules in battery environments.

### SUMMARY OF INVENTION

It is an objective of the present invention to provide a system and a method to address the aforementioned shortcomings and unmet needs in the state of the art.

The present invention provides a hybrid high-throughput density functional theory (DFT) and machine learning (ML) framework for predicting redox potentials of electrolytes. By integrating high-throughput calculation and machine learning, the present invention provides a prediction platform for electrolyte redox potentials, thereby supporting evaluation and screening of electrolyte candidates. The technical solutions of the present invention provide at least three technical means, including Database Setup with Two Thermodynamic Cycle Patterns, Machine Learning Optimization, and Mechanistic Interpretability.

1: Database Setup with Two Thermodynamic Cycle Patterns. The present invention quantifies effects of Li⁺ coordination on oxidation pathways and reduction pathways through thermodynamic cycle method. Through DFT calculations conducted for a plurality of electrolyte molecules, the present invention is capable of evaluating how Li+ coordination influences oxidation and reduction behavior, including electrostatic interactions and ion-dipole interactions associated with redox processes.

2: Machine Learning Optimization. The present invention extracts a plurality of molecular descriptors from SMILES substrings and DFT outputs, including electronic features and structural features associated with frontier orbital energies and bond topology. The extracted descriptors are employed to establish a machine learning model for predicting redox potentials of electrolyte molecules. In some embodiments, 35 molecular descriptors are used and six machine learning algorithms are employed to provide improved predictive accuracy.

3: Mechanistic Interpretability. The present invention employs SHapley Additive explanations (SHAP) to identify molecular features associated with redox behavior. In some embodiments, oxidation potential is primarily associated with electronic features, and reduction potential is primarily associated with structural motifs. Accordingly, the present invention provides interpretability for redox potential prediction and offers guidance for electrolyte design and screening.

In accordance with a first aspect of the present invention, a redox-potential prediction system for evaluating and screening candidate electrolyte molecules under lithium-ion-coordinated conditions for rechargeable lithium-ion batteries is provided. The redox-potential prediction system comprises: a candidate electrolyte collection module, a first-principles computation module, a feature extraction module, a feature engineering module, a model training module, a model evaluation module, an interpretability analysis module, and a redox prediction output module. The candidate electrolyte collection module is configured to collect candidate electrolyte molecules for subsequent redox-potential prediction processing. The first-principles computation module is configured to receive the candidate electrolyte molecules and to perform first-principles computation on the candidate electrolyte molecules under a lithium-ion-coordinated condition so as to generate redox-potential-related computational data. The feature extraction module is configured to receive the redox-potential-related computational data and to extract electronic features and structural features associated with the candidate electrolyte molecules. The feature engineering module is configured to receive the electronic features and the structural features and to generate a processed feature set for subsequent machine-learning-based prediction. The model training module is configured to receive the processed feature set, to construct one or more machine-learning-based prediction models for redox-potential prediction of the candidate electrolyte molecules, and to generate trained-model-related data based on the one or more machine-learning-based prediction models. The model evaluation module is configured to receive the trained-model-related data, to evaluate prediction performance of the one or more machine-learning-based prediction models, and to generate model-evaluation-related data and prediction-related data. The interpretability analysis module is configured to receive the model-evaluation-related data, to determine how different molecular descriptors contribute to oxidation-potential-related prediction and reduction-potential-related prediction, and to generate interpretability-related data. The redox prediction output module is configured to receive the prediction-related data and the interpretability-related data, and to output oxidation-potential prediction results, reduction-potential prediction results, or both, associated with the candidate electrolyte molecules.

In accordance with a second aspect of the present invention, a method for evaluating and screening candidate electrolyte molecules under lithium-ion-coordinated conditions for rechargeable lithium-ion batteries is provided. The method includes steps as follows: collecting candidate electrolyte molecules for subsequent redox-potential prediction processing; performing first-principles computation on the candidate electrolyte molecules with or without a lithium-ion-coordinated condition so as to generate a redox-potential-related computational dataset; extracting electronic features and structural features associated with the candidate electrolyte molecules from the redox-potential-related computational data; generating a processed feature set based on the electronic features and the structural features for subsequent machine-learning-based prediction; constructing one or more machine-learning-based prediction models for redox-potential prediction of the candidate electrolyte molecules based on the processed feature set; evaluating prediction performance of one or more machine-learning-based prediction models; determining how different molecular descriptors contribute to oxidation potential prediction and reduction potential prediction; and outputting oxidation potential prediction results, reduction potential prediction results, or both, associated with the candidate electrolyte molecules.

### BRIEF DESCRIPTION OF DRAWINGS

Embodiments of the invention are described in more details hereinafter with reference to the drawings, in which:

FIG. 1 shows an exemplary workflow for predicting redox potentials of electrolyte molecules according to some embodiments of the present invention;

FIG. 2 shows plots of predicted oxidation potentials and predicted reduction potentials generated by an XGB model in comparison with corresponding DFT-calculated values according to some embodiments of the present invention;

FIG. 3 shows feature-importance distributions associated with redox potential prediction results of the trained machine learning model according to some embodiments of the present invention;

FIG. 4 shows a redox-potential prediction system according to some embodiments of the present invention;

FIG. 5 shows an exemplary machine-learning-based redox potential prediction flow implemented by the redox potential prediction system of FIG. 4; and

FIG. 6 shows a redox potential prediction system according to some embodiments of the present invention.

### DETAILED DESCRIPTION OF THE INVENTION

In the following description, systems and methods for intelligent prediction of redox potentials of electrolyte molecules and the likes are set forth as preferred examples. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

The present invention provides a hybrid computational framework for predicting the redox potentials of lithium-coordinated electrolytes in rechargeable lithium-ion batteries (LiBs). The framework integrates high-throughput density functional theory (DFT) calculations with six types of machine learning (ML) algorithm models implemented from the scikit-learn package, including extreme gradient boosting (XGB), random forest regression (RFR), gradient boosting regression (GBR), support vector regression (SVR), k-neighbor regression (KNR), and Multilayer Perceptron (MLP) to quantify effects of lithium-ion (Li⁺) coordination on redox behavior and to address limitations of conventional thermodynamic cycle methods.

Specifically, the present invention generates a dataset by performing DFT calculations using general thermodynamic cycle method for electrolyte molecules in Li⁺-coordinated states and non-Li⁺-coordinated states so as to evaluate oxidation (Eₒₓ) and reduction (E_{red}) potentials. Through molecular feature engineering, 35 structural and electronic descriptors, such as HOMO/LUMO energies, C═O bond, and molecular polarizability, are extracted from DFT outputs and SMILES substrings. The extracted descriptors are employed to train six types of machine learning (ML) algorithm models for redox potential prediction. In some embodiments, the XGBoost regression model provides higher predictive accuracy, including higher R² and lower RMSE, relative to other machine learning algorithms. In addition, SHapley Additive explanations (SHAP) analysis is employed to identify feature contributions associated with redox behavior, in which oxidation potentials are primarily associated with electronic features, while reduction potentials are associated with structural motifs.

Based on the above framework, electrolyte molecules responsive to Li⁺ coordination may be screened according to electrochemical stability characteristics. The framework further supports selection and design of electrolyte molecules having desired electrochemical stability windows and compatibility with battery electrodes, including high-voltage cathodes, thereby supporting development of lithium-ion batteries having improved energy density, cycle life, and safety.

To facilitate understanding of the present invention, the following description first sets forth technical support regarding the working mechanism underlying the present invention. A specific system architecture for implementing the foregoing working mechanism is then described.

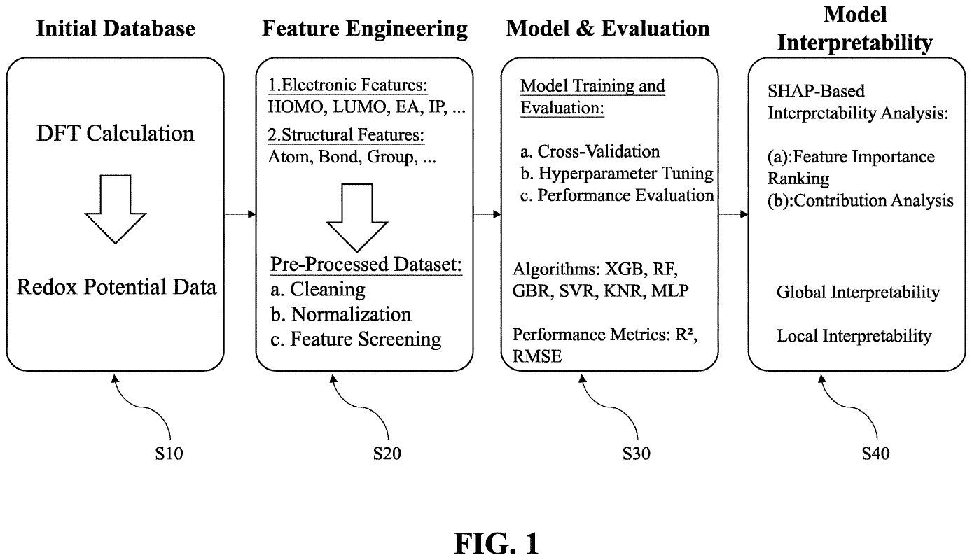

FIG. 1 shows an exemplary workflow for predicting redox potentials of electrolyte molecules. The workflow includes: step S10 of initial database construction and data generation, step S20 of feature engineering and feature selection, step S30 of machine learning methodology for model training and evaluation, and step S40 of interpretability analysis. In the workflow of FIG. 1, the fundamental process for the machine-learning paradigm includes data generation, feature selection, model training, and evaluation, followed by interpretability analysis for understanding how features influence target variables.

At step S10, first-principles computation is performed for initial database construction. In some embodiments, initial electrolyte components are extracted from previously reported theoretical literature and experimental literature, and molecular derivatives having diverse backbone structures are included so as to improve model transferability and to enable the model to learn generalized features from varied structures. In some embodiments, redox-potential-related data points are derived through density functional theory (DFT) calculations and stored in the initial database for subsequent processing.

At step S20, feature engineering is performed on the data obtained from step S10. Feature engineering is an important process for constructing a machine learning model because irrelevant descriptors and redundant descriptors may be removed, thereby shortening training time, reducing overfitting or underfitting, and improving model interpretability. In some embodiments, the collected raw data are pre-processed by removing null values and performing data standardization or normalization. Electronic features and structural features are then extracted and screened to form a pre-processed dataset for machine learning.

At step S30, machine learning methodology is performed for model training and evaluation. In some embodiments, six machine learning algorithms are applied for training, including extreme gradient boosting (XGB), random forest regression (RFR), gradient boosting regression (GBR), support vector regression (SVR), k-neighbor regression (KNR), and multilayer perceptron (MLP). Model evaluation is performed based on two key metrics: coefficient of determination (R²) and root mean squared error (RMSE). In some embodiments, cross-validation and hyperparameter tuning are further employed to determine model stability and accuracy.

At step S40, interpretability analysis is performed on the well-trained model.

In some embodiments, SHAP analysis is applied to rank feature importance and to analyze contributions of feature values to target values, thereby providing a deeper understanding of how molecular features influence redox potentials.

The foregoing workflow of FIG. 1 provides an overall process for predicting redox potentials of electrolyte molecules. The following description further sets forth first-principles computation, feature engineering, and machine learning methodology associated with the workflow of FIG. 1, so as to explain data generation, feature processing, and model construction in greater detail.

### (I) First-Principles Computation:

In the present invention, first-principles computation is employed to establish a computational basis for redox-potential prediction. More specifically, a general thermodynamic cycle method for calculating redox potential may be categorized into two cases, including a case involving lithium coordination and a case without lithium coordination. According to the foregoing thermodynamic cycles, Gibbs free energy changes associated with oxidation and reduction of M/LiM⁺ species in solution may be determined so as to characterize redox behavior of electrolyte molecules under coordination-related conditions.

In some embodiments, the Gibbs free energy change of oxidation,

$$Δ {G}_{solv}^{ox} ( M / {LiM}^{+} ) ,$$

and the Gibbs free energy change of reduction,

$$Δ {G}_{solv}^{red} ( M / {LiM}^{+} ) ,$$

for M/LiM⁺ species in solution are calculated according to Equation (1) and Equation (2), respectively:

$$Δ {G}_{solv}^{ox} ( M / {LiM}^{+} ) = Δ {G}_{gas}^{ox} ( M / {LiM}^{+} ) + Δ {G}_{solv}^{ox} ( {M}^{+} / {LiM}^{2 +} ) - Δ {G}_{solv}^{neut} ( M / {LiM}^{+} ) \qquad ( 1 )$$

$$Δ {G}_{solv}^{red} ( M / {LiM}^{+} ) = Δ {G}_{gas}^{red} ( M / {LiM}^{+} ) + Δ {G}_{solv}^{red} ( {M}^{-} / LiM ) - Δ {G}_{solv}^{neut} ( M / {LiM}^{+} ) \qquad ( 2 )$$

Here,

$$Δ {G}_{gas}^{ox} ( M / {LiM}^{+} )$$

and

$$Δ {G}_{gas}^{red} ( M / {LiM}^{+} )$$

represents oxidation Gibbs free energy and reduction Gibbs free energy, respectively, for M/LiM⁺ species in the gas phase. In addition, the solvation energy term ΔGₛₒₗᵥ is estimated based on an energy required to transfer neutral molecules or charged molecules from a vacuum phase to a liquid phase. Based on the above free-energy values, a standard oxidation potential and a standard reduction potential for molecules with respect to a Li/Li+ reference electrode is defined according to Equation (3) and Equation (4), respectively:

$${E}_{ox} = \frac{Δ {G}_{solv}^{ox} ( M / {LiM}^{+} )}{nF} - 1.44 \qquad ( 3 )$$

$${E}_{red} = \frac{- Δ {G}_{solv}^{red} ( M / {LiM}^{+} )}{nF} - 1.44 \qquad ( 4 )$$

To balance computational precision and computational cost, full geometry optimization is carried out at an M06-2X/6-311++G(d,p) level in a solution phase. In some embodiments, such a computational setting is adopted for redox-potential calculation. Dispersion interaction is considered through empirical dispersion correction D3, and solvation effect is considered through a solvation model based on density (SMD). In some embodiments, a dielectric constant (ε) of 20 is selected so as to represent conditions associated with common mixed carbonate electrolytes. In addition, when ε is greater than 20, influence of the dielectric constant on redox potential may remain limited.

In some embodiments, Gibbs free energy is calculated at a temperature of 323.15 K. Vibration analysis is further carried out to determine whether each optimized geometry corresponds to a minimum point on a potential-energy surface and has no imaginary frequency. For Li⁺-coordinated complexes, binding configurations of Li⁺ to oxygen atoms, nitrogen atoms, and sulfur atoms of electrolyte molecules are screened, and the most energetically stable configuration are selected for subsequent analysis. In some embodiments, all DFT calculations are carried out using Gaussian 16 software.

Explained in another way, the foregoing first-principles computation can be understood as a process for generating redox-potential-related computational data for electrolyte molecules by separately evaluating a lithium-coordinated state and a non-lithium-ion-coordinated state of each electrolyte molecule. More specifically, the process includes obtaining molecular structures of candidate electrolyte molecules, constructing corresponding calculation models for coordinated and non-coordinated conditions, performing quantum-chemical calculation for the molecular structures under the respective conditions, and generating oxidation-related data and reduction-related data associated with the candidate electrolyte molecules.

In some embodiments, the foregoing process further includes determining gas-phase energy information, determining solvation-related energy information, and correlating the gas-phase energy information and the solvation-related energy information so as to obtain redox-potential-related information of the candidate electrolyte molecules relative to a lithium reference system. In some embodiments, the process further includes selecting a coordination configuration of a lithium ion with respect to a heteroatom-containing site of the electrolyte molecule, including an oxygen-containing site, a nitrogen-containing site, or a sulfur-containing site, and using a selected coordination configuration for subsequent redox-related computation.

In some embodiments, the foregoing process further includes performing geometry optimization for each candidate electrolyte molecule or coordinated complex, performing vibration checking on an optimized geometry, determining whether the optimized geometry corresponds to a minimum point on a potential-energy surface, and in response to the optimized geometry satisfying a minimum-point condition, storing corresponding redox-potential-related data as computational support data for subsequent processing. The resulting computational support data will then be provided to a subsequent feature engineering stage to derive molecular descriptors, and further provided to a subsequent machine learning stage to establish a prediction model for redox potentials of electrolyte molecules.

### Feature Engineering

In the present invention, feature engineering is performed to generate input characteristics for subsequent machine-learning-based prediction. In some embodiments, molecular features are classified into energy-based features and structure-based features. The energy-based features include energetically relevant properties associated with electron-transfer capability, including highest occupied molecular orbital (HOMO), lowest unoccupied molecular orbital (LUMO), electron affinity (EA), ionization potential (IP), and lithium-binding energy (Ep). The structure-based features are associated with molecular architecture and include elemental composition, bond types, ring structures, and functional groups.

In some embodiments, structural features are extracted from simplified molecular input line entry system (SMILES) representations of electrolyte molecules, and energy-based features are derived from first-principles computational results. The collected features are then subjected to preprocessing so as to remove incomplete data and reduce feature redundancy. In some embodiments, features having empty values are removed before subsequent screening and selection.

To evaluate correlation between features, a Pearson correlation coefficient is calculated between pairs of features, as shown in Equation (5).

$$ρ = \frac{\sum ( {X}_{i} - \overline{X} ) ( {Y}_{i} - \overline{Y} )}{\sqrt{\sum {( {X}_{i} - \overline{X} )}^{2} \sum {( {Y}_{i} - \overline{Y} )}^{2}}} \qquad ( 5 )$$

where Xᵢ and Yᵢ represent sample data points, and X̅ and Y represent mean values of variables X and Y, respectively. The Pearson correlation coefficient ρ ranges from +1 to −1, wherein values closer to +1 indicate stronger positive correlation and values closer to −1 indicate stronger negative correlation between features. Based on the correlation results, features having reduced redundancy and improved independence may be reserved as input characteristics for machine learning processing.

In some embodiments, features are selected according to an absolute Pearson correlation coefficient threshold of less than or equal to 0.9. Through the above screening process, 35 features are reserved as input characteristics. Such reserved features exhibit relatively weak inter-feature correlation and provide a low-redundancy feature set for subsequent model training, thereby supporting improved prediction performance and model interpretability.

Explained in another way, the foregoing feature engineering may be understood as a process for generating input features for machine-learning-based redox-potential prediction by combining electronic features and structural features of electrolyte molecules. The process may include preprocessing collected feature data, removing incomplete feature entries, evaluating correlation between features, and screening features according to a correlation threshold so as to retain a reduced-redundancy feature set.

### Machine Learning Methodology

In the present invention, machine learning methodology is performed to establish and evaluate a redox-potential prediction model based on data obtained from first-principles computation and feature engineering. In some embodiments, original data obtained from DFT calculations are randomly divided into a training set and a test set according to a ratio of 8:2. Data normalization is then performed after data splitting so that feature values are scaled in a consistent manner.

In some embodiments, a plurality of machine learning algorithms is employed for model training, including extreme gradient boosting (XGB), random forest regression (RFR), gradient boosting regression (GBR), support vector regression (SVR), k-neighbor regression (KNR), and multilayer perceptron (MLP). For each machine learning algorithm, cross-validation and hyperparameter tuning may be performed to determine model stability and prediction accuracy.

Model performance may be evaluated based on a root-mean-squared error (RMSE) metric and a coefficient of determination (R²) metric, as shown in Equation (6) and Equation (7), respectively.

$$RMSE = \sqrt{\frac{{\sum }_{i = 1}^{N} {( {y}_{i} - {\hat{y}}_{i} )}^{2}}{N}} \qquad ( 6 )$$

$${R}^{2} = 1 - \frac{{\sum }_{i = 1}^{N} {( {y}_{i} - {\hat{y}}_{i} )}^{2}}{{\sum }_{i = 1}^{N} {( {y}_{i} - \overline{y} )}^{2}} \qquad ( 7 )$$

where N represents a total number of data points, yᵢ represents a calculated value for a data point, ŷᵢ represents a predicted value for the data point, and y̅ represents an average of observed values in the dataset. In some embodiments, to reduce variability introduced by random data splitting during different training rounds, final R² and RMSE values are obtained by averaging results over 500 iterations of training and testing.

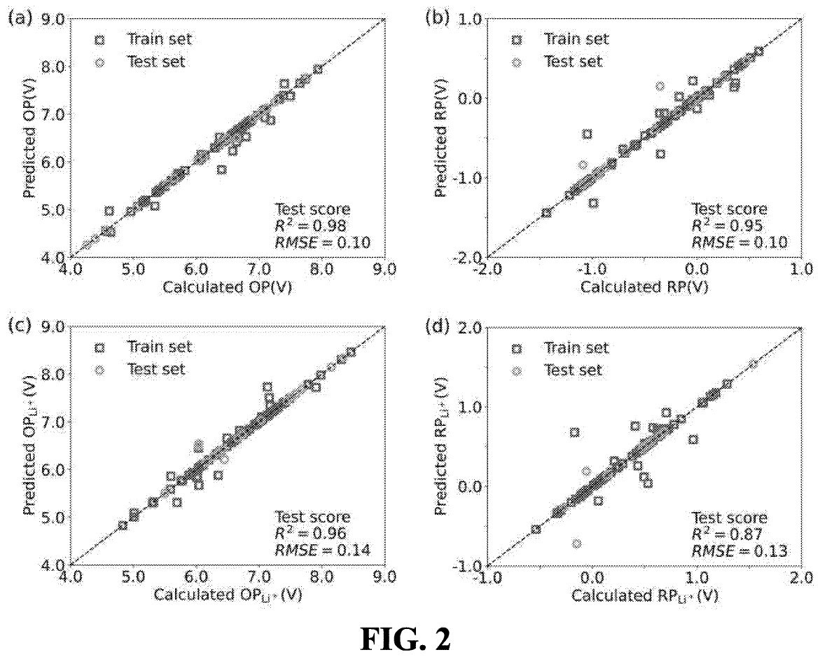

FIG. 2 shows plots of predicted oxidation potentials and predicted reduction potentials generated by an XGB model in comparison with corresponding DFT-calculated values. More specifically, in FIG. 2, parts (a) and (c) correspond to oxidation-potential prediction results, and parts (b) and (d) correspond to reduction-potential prediction results. In each plot, predicted values are compared against calculated values for both a training set and a test set, so as to illustrate agreement between model output and first-principles computation results.

As shown in FIG. 2, data points of the training set and the test set are distributed in proximity to a diagonal reference trend, indicating that the trained XGB model provides prediction results consistent with the DFT-calculated oxidation potentials and reduction potentials. Accordingly, FIG. 2 demonstrates that the machine learning model established according to the foregoing methodology is capable of learning a relationship between molecular descriptors and redox potential, and may therefore be used for redox potential prediction of electrolyte molecules.

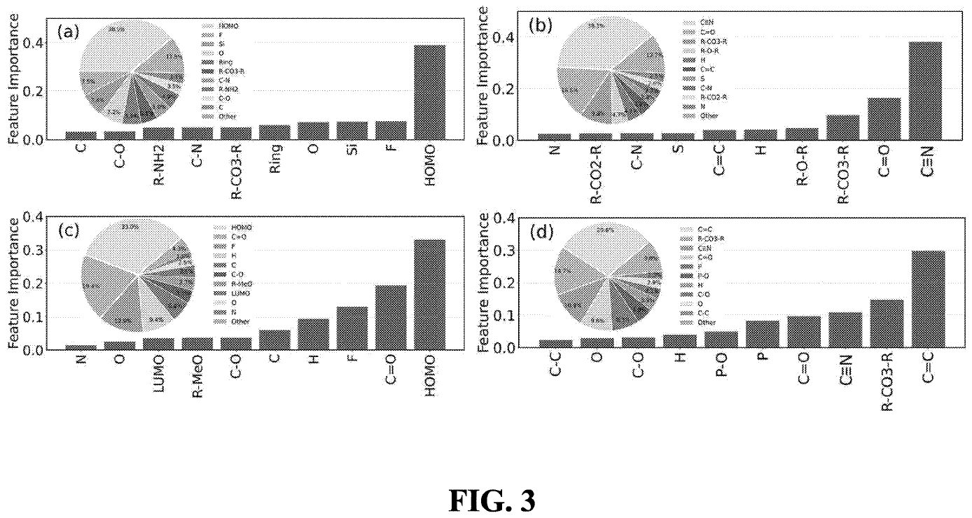

FIG. 3 shows feature-importance distributions associated with redox potential prediction results of the trained machine learning model. More specifically, in FIG. 3, parts (a) to (d) illustrate relative contributions of different molecular features in different prediction tasks, so as to indicate how the model distinguishes among candidate electrolyte molecules based on electronic features and structural features.

In some embodiments, in FIG. 3, parts (a) and (c) show that oxidation potential prediction is primarily associated with electronic-feature-related descriptors, including orbital-related descriptors, whereas parts (b) and (d) show that reduction potential prediction is more strongly associated with structural-feature-related descriptors, including bond-related descriptors and functional-group-related descriptors. Accordingly, FIG. 3 provides interpretability regarding how the trained model determines redox potential and further provides a basis for screening candidate electrolyte molecules according to target oxidation characteristics or target reduction characteristics.

Explained in another way, the foregoing machine learning methodology may be understood as a process for constructing a redox potential prediction model from computation-derived molecular data. More specifically, the process includes dividing the molecular data into a training dataset and a testing dataset, normalizing feature values of the divided datasets, and training a plurality of prediction models.

In some embodiments, the foregoing machine learning methodology further includes evaluating prediction performance of the plurality of prediction models according to an error metric and a goodness-of-fit metric, comparing the prediction performance of the plurality of prediction models, and selecting a model having improved prediction stability and accuracy. In some embodiments, training and testing are repeated over a plurality of iterations so as to reduce variability caused by random data splitting, and averaged evaluation results are used to determine final model performance for redox potential prediction.

The foregoing description sets forth the computational basis, feature construction basis, and machine-learning basis for redox potential prediction of electrolyte molecules. Based on the foregoing technical basis, the present invention may further be embodied as a concrete redox potential prediction apparatus or system configured to receive electrolyte-related input data, perform coordinated computational processing and model-based prediction, and output redox potential prediction results for battery-related applications. Accordingly, the present invention is not limited to abstract mathematical analysis, but may be implemented as a practical system for processing candidate electrolyte information and generating prediction outputs usable for electrolyte evaluation and screening.

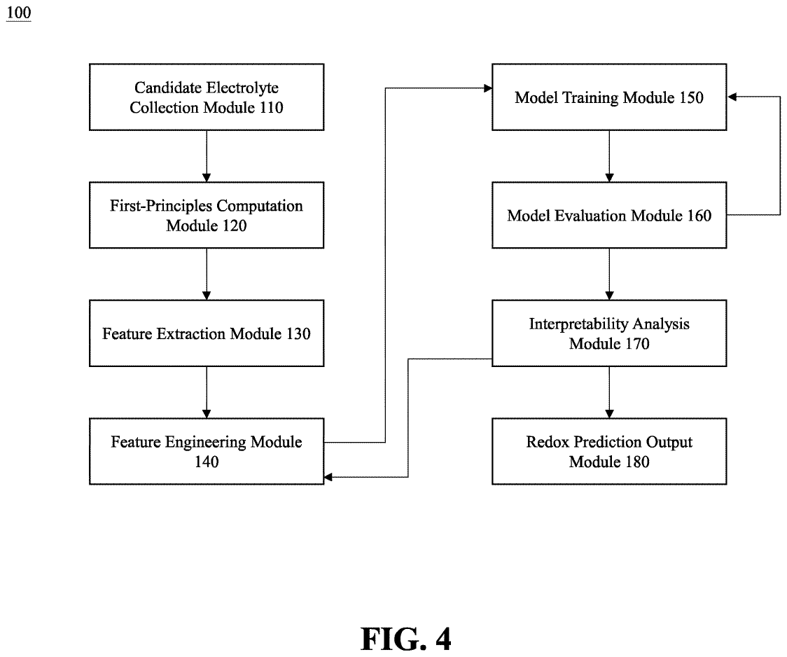

FIG. 4 shows a redox potential prediction system 100 according to some embodiments of the present invention. The redox potential prediction system 100 may be applied to prediction of oxidation potentials and reduction potentials of candidate electrolyte molecules, particularly under lithium-ion-coordinated conditions, so as to support evaluation and screening of electrolyte materials for rechargeable lithium-ion batteries (LiBs).

In some embodiments, the redox potential prediction system 100 may be used to identify candidate electrolyte molecules having desired electrochemical stability characteristics, including compatibility with wide electrochemical windows and high-voltage cathodes. The redox potential prediction system 100 may receive, as input, candidate electrolyte components, molecular structure information, first-principles computation data, or feature data derived therefrom, and may process the input data through a plurality of functional modules. As a result of such processing, the redox potential prediction system 100 may output predicted redox potential results, including oxidation potential prediction results, reduction potential prediction results, feature-importance-related results, or interpretability-related results associated with candidate electrolyte molecules. In this regard, direct outputs of the redox potential prediction system 100 include model-based prediction results and interpretability-related results associated with candidate electrolyte molecules, and such direct outputs may further be used to generate a retained candidate set for subsequent electrolyte formulation, validation, or battery-development processing.

The redox-potential prediction system 100 includes a candidate electrolyte collection module 110, a first-principles computation module 120, a feature extraction module 130, a feature engineering module 140, a model training module 150, a model evaluation module 160, an interpretability analysis module 170, and a redox prediction output module 180. The foregoing modules may be communicatively coupled to one another through wired connections, wireless connections, or combinations thereof, so that data, feature values, intermediate results, model parameters, and prediction results may be transmitted among the modules. In some embodiments, the foregoing modules may be implemented by one or more processors, logic circuits, control circuits, memory units, or combinations thereof, and may exchange information with one another to cooperatively perform candidate collection, computational data generation, feature processing, model construction, model evaluation, interpretability analysis, and redox potential prediction output.

The candidate electrolyte collection module 110 is configured to collect candidate electrolyte molecules for subsequent redox potential prediction processing. The candidate electrolyte collection module 110 is not configured to indiscriminately gather molecular data, but is configured to selectively construct a candidate set of electrolyte molecules according to molecular diversity and battery-related applicability. More specifically, the candidate electrolyte collection module 110 is configured to collect electrolyte components from theoretical literature, experimental literature, existing electrolyte datasets, or combinations thereof, and to preferentially retain candidate electrolyte molecules having diverse backbone structures, diverse functional-group characteristics, or diverse coordination-capable sites, so that subsequent model construction is based on a dataset capable of representing varied electrolyte chemistries. In this regard, the candidate electrolyte collection module 110 is configured to use lithium-ion coordination capability as one collection criterion, so as to preferentially retain candidate electrolyte molecules having coordination-capable atomic sites for subsequent lithium-ion-coordinated redox-potential processing.

The candidate electrolyte collection module 110 is further configured to collect candidate electrolyte molecules including molecules associated with different molecular architectures, different bond types, different cyclic or non-cyclic structures, and different heteroatom-containing groups capable of interacting with lithium ions. In some embodiments, the candidate electrolyte molecules include carbonate-based compounds, carboxylate-based compounds, ether-based compounds, sulfur-containing compounds, phosphorus-containing compounds, nitrile-based compounds, boron-based compounds, or combinations thereof. In some embodiments, the candidate electrolyte molecules are selected from candidate components associated with multiple solvent systems, multifunctional additives, or both, for battery applications requiring high-voltage operation, broad temperature adaptability, or safety performance. Through such selective collection, the candidate electrolyte collection module 110 is configured to improve transferability of a subsequently trained prediction model and to enable subsequent modules to learn generalized redox-related patterns from structurally differentiated electrolyte molecules, rather than from narrowly repeated molecular types.

The candidate electrolyte collection module 110 is further configured to output candidate-molecule-identification data, molecular structure information, source-related information, or combinations thereof to the first-principles computation module 120, so that the first-principles computation module 120 can perform lithium-coordination-related computation on candidate electrolyte molecules selected according to the foregoing collection criteria.

The first-principles computation module 120 is configured to receive candidate electrolyte molecules from the candidate electrolyte collection module 110 and to perform first-principles computation on the candidate electrolyte molecules so as to generate redox-potential-related computational data. More specifically, the first-principles computation module 120 is configured to evaluate redox behavior of each candidate electrolyte molecule under a lithium-ion-coordinated condition and, optionally, under a non-lithium-ion-coordinated condition, thereby forming thermodynamic-cycle-related computational data for oxidation-related processing and reduction-related processing. Through such computation, oxidation-related information, reduction-related information, and coordination-related information can be obtained for subsequent processing.

The first-principles computation module 120 is configured to calculate electronic-related parameters and redox-potential-related values associated with the candidate electrolyte molecules. The first-principles computation module 120 may be configured to generate, for each candidate electrolyte molecule, gas-phase-energy-related information, solvation-related information, oxidation-potential-related information, reduction-potential-related information, or combinations thereof. The first-principles computation module 120 is configured to perform lithium-ion-coordination-aware computation, so that the generated computational data reflects redox behavior of electrolyte molecules in a lithium-ion-coordinated environment rather than only in an isolated molecular state. In some embodiments, the first-principles computation module 120 is configured to quantify influences of electrostatic interaction, ion-dipole interaction, or both on oxidation behavior and reduction behavior of the candidate electrolyte molecules.

The first-principles computation module 120 is further configured to identify or screen coordination-capable atomic sites of the candidate electrolyte molecules, including oxygen-containing sites, nitrogen-containing sites, sulfur-containing sites, or combinations thereof, and to determine coordination configurations associated with lithium ions. The first-principles computation module 120 may be configured to evaluate a plurality of candidate coordination configurations and to retain a coordination configuration having higher stability for subsequent computation. Through such processing, the first-principles computation module 120 is configured to provide coordination-sensitive computational data usable for subsequent feature extraction and model construction.

The first-principles computation module 120 may further be configured to perform geometry optimization, solvation-effect-related computation, free-energy-related computation, vibration analysis, or combinations thereof, so as to obtain an optimized molecular geometry for subsequent redox-related evaluation.

Computational results generated by the first-principles computation module 120 may be transmitted to the feature extraction module 130 as input data for deriving electronic features, redox-potential-related features, coordination-related features, or combinations thereof.

The feature extraction module 130 is configured to receive computational data generated by the first-principles computation module 120 and to convert the computational data into structured feature-source data suitable for descriptor extraction. More specifically, the feature extraction module 130 is configured to parse, organize, correlate, and reformat redox-potential-related computational results, electronic-parameter-related results, solvation-related results, coordination-related results, or combinations thereof, so that computational outputs generated in a calculation-result form are transformed into machine-readable feature-source data associated with respective candidate electrolyte molecules.

Based on the foregoing structured feature-source data, the feature extraction module 130 is configured to extract feature data from the computational data and molecular-structure-related data of candidate electrolyte molecules. More specifically, the feature extraction module 130 is configured to convert redox-potential-related computational results, electronic-parameter-related results, solvation-related results, coordination-related results, or combinations thereof into feature values usable for subsequent machine-learning-based processing.

The feature extraction module 130 is configured to extract electronic features and structural features associated with each candidate electrolyte molecule. The electronic features may include highest occupied molecular orbital (HOMO)-related information, lowest unoccupied molecular orbital (LUMO)-related information, electron-affinity (EA)-related information, ionization-potential (IP)-related information, lithium-binding-energy (Eb)-related information, or combinations thereof. The structural features may include elemental-composition-related information, bond-type-related information, ring-structure-related information, functional-group-related information, number-of-functional-group-related information, cyclic-structure-presence-related information, or combinations thereof. The foregoing structural features may be extracted from molecular structure representations of the candidate electrolyte molecules, including simplified molecular input line entry system (SMILES) representations, molecular fingerprint encoding, or other molecular structure descriptions.

The feature extraction module 130 is further configured to generate feature data reflecting lithium-ion-coordinated redox behavior of the candidate electrolyte molecules. For example, the feature extraction module 130 is configured to extract, from the computational data generated under lithium-ion-coordinated conditions, electronic descriptors and redox-related descriptors associated with coordination-sensitive molecular behavior, so that the extracted feature data are not limited to isolated-molecule properties but reflect lithium-ion-coordination-related effects relevant to battery environments.

The feature extraction module 130 is further configured to associate the extracted electronic features and the extracted structural features with corresponding candidate electrolyte molecules and to output combined feature data to the feature engineering module 140.

The feature engineering module 140 is configured to receive the combined feature data output by the feature extraction module 130 and to generate a processed feature set for subsequent machine-learning-based prediction. More specifically, the feature engineering module 140 is configured to preprocess, organize, and screen the extracted electronic features and structural features so that feature data associated with candidate electrolyte molecules can be transformed into input characteristics suitable for model training and model evaluation.

The feature engineering module 140 is configured to perform data-cleaning-related processing on the combined feature data. In some embodiments, the feature engineering module 140 is configured to identify incomplete feature entries, remove feature entries having empty values, and align remaining feature values with corresponding candidate electrolyte molecules. The feature engineering module 140 may further be configured to normalize feature values so that feature data of different scales or types can be represented in a consistent form for subsequent machine-learning-based processing.

The feature engineering module 140 is further configured to perform feature-screening-related processing on the combined feature data so as to reduce feature redundancy. The feature engineering module 140 is configured to evaluate correlation between different features, identify features exhibiting relatively high correlation, and retain features having reduced redundancy and improved independence. In some embodiments, the feature engineering module 140 is configured to calculate a Pearson correlation coefficient between pairs of features and to screen features according to an absolute Pearson correlation threshold less than or equal to 0.9, so that a low-redundancy feature set is generated for subsequent model construction.

The feature engineering module 140 is configured to retain a screened feature subset including electronic-feature-related descriptors and structural-feature-related descriptors for each candidate electrolyte molecule. In some embodiments, the screened feature subset includes 35 descriptors obtained after redundancy reduction and correlation-based screening. Through such processing, the feature engineering module 140 is configured to provide a reduced-redundancy input feature set that supports shortened training time, reduced overfitting or underfitting, and improved interpretability of a subsequently trained redox potential prediction model.

The feature engineering module 140 is further configured to output the processed feature set to the model training module 150. In some embodiments, the processed feature set includes screened feature data corresponding to candidate electrolyte molecules under lithium-ion-coordinated redox-related conditions, so that subsequent machine-learning-based processing is performed on features reflecting coordination-sensitive molecular behavior rather than only unscreened raw feature data.

The model training module 150 is configured to receive the processed feature set output by the feature engineering module 140 and to construct one or more machine-learning-based prediction models for redox potential prediction of candidate electrolyte molecules. More specifically, the model training module 150 is configured to use screened electronic-feature-related descriptors and structural-feature-related descriptors as input variables and to use oxidation potential and reduction potential as target variables, so that one or more prediction models can be trained to learn a correspondence between molecular descriptors and redox potential outputs. In some embodiments, the processed feature set forms a multi-dimensional feature dataset integrating quantum-chemical characteristics and molecular-structure-related characteristics.

The model training module 150 is configured to train a plurality of machine learning models based on the processed feature set. The plurality of machine learning models may include an extreme gradient boosting model (XGB), a random forest regression model, a gradient boosting regression model, a support vector regression model, a k-neighbor regression model, a multilayer perceptron model, or combinations thereof. Through such processing, the model training module 150 is configured to generate a plurality of trained candidate models for subsequent evaluation and comparison. In some embodiments, the extreme gradient boosting model is used as a preferred model for subsequent redox potential prediction processing.

The model training module 150 is further configured to perform model-construction-related processing using feature data corresponding to candidate electrolyte molecules under lithium-ion-coordinated conditions. The model training module 150 is configured to establish a prediction relationship between coordination-sensitive molecular descriptors and redox potential, so that the trained machine learning models reflect lithium-ion-coordinated redox behavior rather than only general molecular-property trends.

The model training module 150 may further be configured to generate trained-model-related data including trained model structures, trained model parameters, model-response data, or combinations thereof, and to transmit the trained-model-related data to the model evaluation module 160. Through such processing, the model training module 150 provides a trained model basis for subsequent performance evaluation, model comparison, and selection of a model suitable for redox potential prediction processing.

The model evaluation module 160 is configured to receive trained-model-related data output by the model training module 150 and to evaluate prediction performance of the plurality of trained machine learning models. More specifically, the model evaluation module 160 is configured to determine how accurately each trained machine learning model predicts oxidation potential and reduction potential of candidate electrolyte molecules, so that the plurality of trained machine learning models can be compared with one another on a common evaluation basis.

The model evaluation module 160 is configured to perform training-set-based evaluation and test-set-based evaluation on the plurality of trained machine learning models. In some embodiments, candidate-electrolyte-related data are divided into a training dataset and a testing dataset according to a ratio of 8:2, so that prediction performance of each trained machine learning model can be evaluated under different data subsets. The model evaluation module 160 may further be configured to evaluate model performance according to an error metric and a goodness-of-fit metric, including a root-mean-squared error (RMSE) metric, a coefficient-of-determination metric (R²), or both.

The model evaluation module 160 is further configured to compare prediction performance of the plurality of trained machine learning models and to determine a best-performed model therefrom. In some embodiments, the model evaluation module 160 is configured to use evaluation results associated with a plurality of training and testing rounds to reduce variability caused by random data splitting. In some embodiments, the model evaluation module 160 is configured to obtain averaged evaluation results over 500 iterations, and to identify a selected model having higher coefficient-of-determination performance and lower root-mean-squared-error performance relative to other trained machine learning models. The model evaluation module 160 may be configured to obtain averaged evaluation results over a plurality of iterations, so that model selection is based on stabilized prediction-performance results rather than on a single training result.

The model evaluation module 160 may further be configured to receive cross-validation-related data, hyperparameter-tuning-related data, or combinations thereof, and to determine model stability and model accuracy based thereon. In some embodiments, the cross-validation-related data include five-fold cross-validation data, and the hyperparameter-tuning-related data include grid-search-related tuning data. The model evaluation module 160 is further configured to output model-evaluation-related data, model-comparison-related data, best-model-identification data, or combinations thereof to the interpretability analysis module 170 and, optionally, back to the model training module 150 for further adjustment or retraining.

The interpretability analysis module 170 is configured to receive model-evaluation-related data, model-comparison-related data, best-model-identification data, or combinations thereof from the model evaluation module 160 and to perform interpretability analysis on a selected machine learning model. More specifically, the interpretability analysis module 170 is configured to determine how different molecular descriptors contribute to oxidation potential prediction and reduction potential prediction, so that prediction behavior of the selected machine learning model can be interpreted with respect to candidate electrolyte molecules.

The interpretability analysis module 170 is configured to rank importance of a plurality of descriptors associated with the selected machine learning model. In some embodiments, the interpretability analysis module 170 is configured to identify relative contributions of electronic-feature-related descriptors and structural-feature-related descriptors to redox potential outputs, and to determine which descriptors are more strongly associated with oxidation potential prediction and which descriptors are more strongly associated with reduction potential prediction.

The interpretability analysis module 170 may further be configured to perform SHapley Additive explanations (SHAP) analysis or other contribution-analysis processing on the selected machine learning model, so that feature-value contributions to target-value prediction can be determined for individual candidate electrolyte molecules or across a plurality of candidate electrolyte molecules. Through such processing, the interpretability analysis module 170 is configured to generate feature-importance-related data, contribution-analysis-related data, global-interpretability-related data, local-interpretability-related data, or combinations thereof.

The interpretability analysis module 170 is configured to determine that oxidation potential prediction is more strongly associated with electronic-feature-related descriptors, whereas reduction potential prediction is more strongly associated with structural-feature-related descriptors. In some embodiments, the electronic-feature-related descriptors include frontier-orbital-related descriptors, and the structural-feature-related descriptors include bond-related descriptors, functional-group-related descriptors, carbonyl-group-related descriptors, or combinations thereof. The interpretability analysis module 170 is further configured to output interpretability-related data to the redox prediction output module 180 and, optionally, to the feature engineering module 140 so as to support subsequent feature refinement, feature prioritization, or descriptor screening adjustment.

The redox prediction output module 180 is configured to receive prediction-related data, model-evaluation-related data, interpretability-related data, or combinations thereof from one or more upstream modules and to output redox-potential-related results associated with candidate electrolyte molecules. More specifically, the redox prediction output module 180 is configured to output oxidation potential prediction results, reduction potential prediction results, or both, for respective candidate electrolyte molecules processed by the redox potential prediction system 100.

The redox prediction output module 180 is further configured to associate the foregoing prediction results with corresponding candidate electrolyte molecules and to generate output data indicating redox behavior of the candidate electrolyte molecules under lithium-ion-coordinated conditions. In some embodiments, the redox prediction output module 180 is configured to output candidate-specific prediction results, comparative prediction results among a plurality of candidate electrolyte molecules, or ranked prediction results according to oxidation-related characteristics, reduction-related characteristics, or combinations thereof.

The redox prediction output module 180 may further be configured to output feature-importance-related results, contribution-analysis-related results, interpretability-related results, or combinations thereof together with the oxidation potential prediction results and the reduction potential prediction results. Through such processing, the redox prediction output module 180 is configured to provide not only prediction values but also explanatory information indicating how electronic-feature-related descriptors and structural-feature-related descriptors are associated with redox potential outputs.

The redox prediction output module 180 is configured to provide output data usable for candidate-electrolyte evaluation, comparison, or screening in battery-related applications. In some embodiments, the redox prediction output module 180 is configured to provide output data usable for identifying candidate electrolyte molecules suitable for wide electrochemical windows, compatibility with high-voltage cathodes, or both. Accordingly, the redox prediction output module 180 serves as an output interface through which the redox-potential prediction system 100 provides prediction results and interpretability results for subsequent technical use.

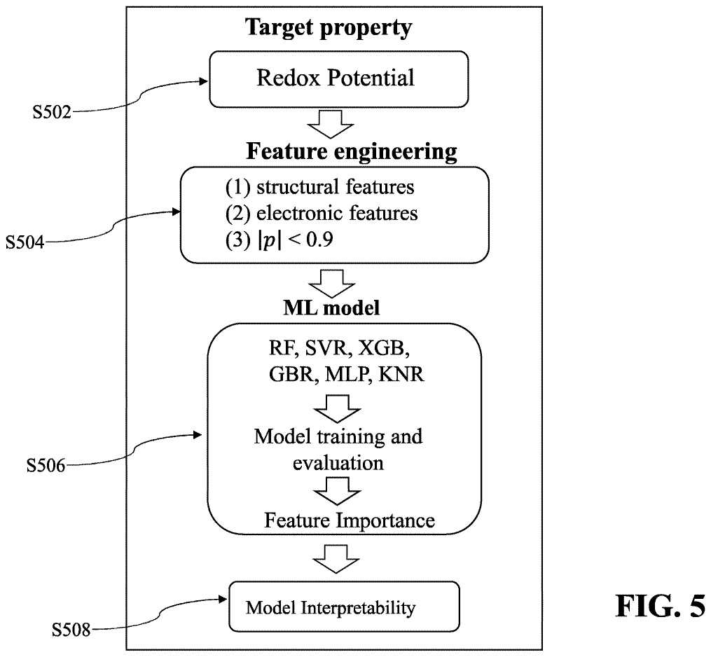

FIG. 5 shows an exemplary machine-learning-based redox potential prediction flow implemented by the redox potential prediction system 100 of FIG. 4. More specifically, FIG. 5 illustrates how a target property is progressively processed through feature engineering, machine learning model construction, and model interpretability analysis, so that redox potential results can be generated for candidate electrolyte molecules. The flow of FIG. 5 may be implemented through cooperative operation among the candidate electrolyte collection module 110, the first-principles computation module 120, the feature extraction module 130, the feature engineering module 140, the model training module 150, the model evaluation module 160, the interpretability analysis module 170, and the redox prediction output module 180 of FIG. 4.

At step S502, the target property is set as redox potential. In some embodiments, the target property includes oxidation potential, reduction potential, or both, of a candidate electrolyte molecule with or without lithium-ion-coordinated conditions. The target property at step S502 may be derived from computational data generated by the first-principles computation module 120 based on candidate electrolyte molecules collected by the candidate electrolyte collection module 110. Through such processing, the redox potential prediction system 100 establishes a prediction task directed to redox behavior with or without lithium-ion-coordinated conditions rather than only general molecular-property estimation.

At step S504, feature engineering is performed on feature data associated with the candidate electrolyte molecules. In some embodiments, step S504 is performed through cooperation between the feature extraction module 130 and the feature engineering module 140. More specifically, the feature extraction module 130 converts computational outputs generated by the first-principles computation module 120 into structured feature-source data and extracts structural features and electronic features therefrom, and the feature engineering module 140 further preprocesses and screens the extracted features. In some embodiments, the screened features include structural features, electronic features, and a reduced-redundancy feature subset selected according to an absolute Pearson correlation threshold, such as |ρ|≤0.9. Through such cooperation, heterogeneous computational results and molecular-structure-related information are transformed into machine-learning-ready descriptors for subsequent model construction, which constitutes one technical contribution of the present invention.

At step S506, machine learning model construction, training, and evaluation are performed. In some embodiments, step S506 is performed through cooperation between the model training module 150 and the model evaluation module 160. More specifically, the model training module 150 is configured to train a plurality of machine learning models based on the processed feature set generated by the feature engineering module 140, and the model evaluation module 160 is configured to evaluate prediction performance of the trained machine learning models. In some embodiments, the model evaluation module 160 evaluates the trained machine learning models according to a coefficient-of-determination (R²) metric, or a root-mean-squared error (RMSE) metric, or both. Through such cooperation, the redox potential prediction system 100 is capable of selecting a model having improved prediction stability and accuracy for redox potential prediction with or without lithium-ion-coordinated conditions.

At step S508, model interpretability analysis is performed. In some embodiments, step S508 is performed through cooperation between the interpretability analysis module 170 and the redox prediction output module 180. More specifically, the interpretability analysis module 170 is configured to rank feature importance and to determine contribution relationships between feature values and target values, and the redox prediction output module 180 is configured to output corresponding interpretability-related results together with redox potential prediction results. Through such processing, the redox potential prediction system 100 not only provides oxidation potential prediction results and reduction potential prediction results but also provides interpretable information indicating how electronic-feature-related descriptors and structural-feature-related descriptors are associated with redox behavior of candidate electrolyte molecules.

In some embodiments, the model evaluation module 160 is further configured to feed model-evaluation-related data back to the model training module 150. Through such feedback, the model training module 150 may adjust model parameters, update training settings, or retrain one or more machine learning models according to evaluation results generated by the model evaluation module 160. Such feedback processing is beneficial in that prediction stability and prediction accuracy may be improved based on evaluation-driven refinement rather than based only on a single-pass model-construction process.

In some embodiments, the interpretability analysis module 170 is further configured to feed interpretability-related data back to the feature engineering module 140. Through such feedback, the feature engineering module 140 may refine feature screening, prioritize descriptors having higher contribution significance, or adjust retention of electronic-feature-related descriptors and structural-feature-related descriptors for subsequent model construction. Such feedback processing is beneficial in that the feature set may be iteratively improved according to contribution-analysis results, thereby supporting reduced redundancy and improved relevance of the input descriptors.

In some embodiments, results output by the redox prediction output module 180 are used to select one or more candidate electrolyte molecules for subsequent battery-related implementation. More specifically, the output results may be used to retain candidate electrolyte molecules having desired oxidation characteristics, desired reduction characteristics, compatibility with wide electrochemical windows, compatibility with high-voltage cathodes, or combinations thereof, to exclude candidate electrolyte molecules failing to satisfy one or more corresponding criteria, and to provide a retained candidate set for subsequent electrolyte formulation, validation, or battery-development processing. Accordingly, the results generated by the redox potential prediction system 100 are used for downstream technical selection and deployment of electrolyte candidates for rechargeable lithium-ion battery development, rather than merely for abstract analytical evaluation.

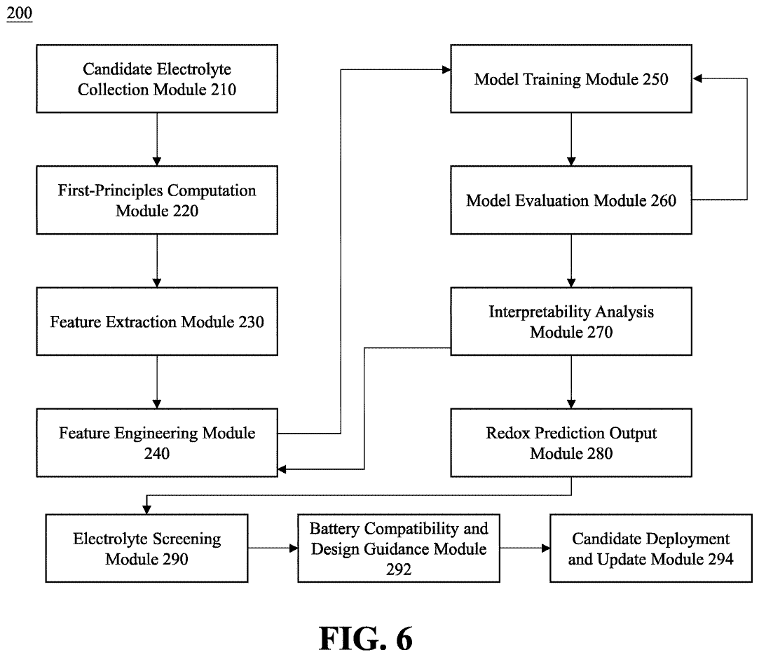

FIG. 6 shows a redox potential prediction system 200 according to some embodiments of the present invention. The redox potential prediction system 200 may be understood as an extended implementation of the redox potential prediction system 100 of FIG. 4.

More specifically, the redox-potential prediction system 200 retains a candidate-electrolyte collection stage, a first-principles computation stage, a feature extraction stage, a feature engineering stage, a model training stage, a model evaluation stage, an interpretability analysis stage, and a redox prediction output stage, and further includes an electrolyte screening module 290, a battery compatibility and design guidance module 292, and a candidate deployment and update module 294. Through such extension, the redox potential prediction system 200 is configured not only to generate model-based prediction results, but also to perform downstream technical screening, battery-related compatibility determination, design guidance generation, and candidate deployment processing.

The redox potential prediction system 200 includes a candidate electrolyte collection module 210, a first-principles computation module 220, a feature extraction module 230, a feature engineering module 240, a model training module 250, a model evaluation module 260, an interpretability analysis module 270, a redox prediction output module 280, the electrolyte screening module 290, the battery compatibility and design guidance module 292, and the candidate deployment and update module 294.

The foregoing modules may be communicatively coupled to one another through wired connections, wireless connections, or combinations thereof, so that candidate-molecule-related data, computational data, feature data, model data, evaluation data, interpretability data, screening data, and deployment-related data may be transmitted among the modules. The foregoing modules may be implemented by one or more processors, logic circuits, control circuits, memory units, or combinations thereof, and may exchange information with one another to cooperatively perform prediction, screening, compatibility determination, design-guidance generation, and downstream battery-related processing.

The candidate electrolyte collection module 210, the first-principles computation module 220, the feature extraction module 230, the feature engineering module 240, the model training module 250, the model evaluation module 260, the interpretability analysis module 270, and the redox prediction output module 280 may respectively correspond in structure and operation to the candidate electrolyte collection module 110, the first-principles computation module 120, the feature extraction module 130, the feature engineering module 140, the model training module 150, the model evaluation module 160, the interpretability analysis module 170, and the redox prediction output module 180 of FIG. 4, and thus repeated description thereof may be omitted where appropriate. The redox prediction output module 280 is configured to output prediction-related results, interpretability-related results, ranked candidate-related results, or combinations thereof to the electrolyte screening module 290 and the battery compatibility and design guidance module 292.

The electrolyte screening module 290 is configured to receive results output by the redox prediction output module 280 and to perform candidate-electrolyte screening according to redox-potential-related criteria. More specifically, the electrolyte screening module 290 is configured to rank, retain, exclude, or otherwise classify candidate electrolyte molecules according to oxidation-potential-related characteristics, reduction-potential-related characteristics, wide-electrochemical-window suitability, or combinations thereof. In some embodiments, the electrolyte screening module 290 is configured to generate a retained candidate set including one or more candidate electrolyte molecules satisfying one or more predetermined redox-related selection criteria.

The battery compatibility and design guidance module 292 is configured to receive screening-related data from the electrolyte screening module 290 and, optionally, prediction-related data or interpretability-related data from the redox prediction output module 280 or the interpretability analysis module 270. More specifically, the battery compatibility and design guidance module 292 is configured to determine whether retained candidate electrolyte molecules are compatible with one or more battery-related operating conditions, including compatibility with high-voltage cathodes, desired electrochemical stability windows, temperature-related requirements, safety-related requirements, or combinations thereof. The battery compatibility and design guidance module 292 is further configured to generate design-guidance-related information based on descriptor contribution relationships identified by the interpretability analysis module 270, so that electronic-feature-related descriptors, structural-feature-related descriptors, or combinations thereof may be used as guidance indicators for subsequent electrolyte design or refinement.

The candidate deployment and update module 294 is configured to receive compatibility-related data, design-guidance-related data, retained-candidate-set-related data, or combinations thereof, and to perform downstream processing on candidate electrolyte molecules selected by the redox potential prediction system 200. More specifically, the candidate deployment and update module 294 is configured to generate a recommended candidate set for subsequent electrolyte formulation, validation, battery-development processing, or combinations thereof.

In some embodiments, the candidate deployment and update module 294 is further configured to receive downstream validation-related information and to provide corresponding update-related data for subsequent model refinement, database supplementation, feature adjustment, or combinations thereof.

In some embodiments, the candidate deployment and update module 294 is further configured to convert the recommended candidate set into machine-executable control instructions. The machine-executable control instructions may be transmitted to an automated material synthesis system, a robotic dispensing apparatus, or both, so that selected candidate electrolyte molecules are physically formulated into electrolyte samples. In some embodiments, the candidate deployment and update module 294 is further configured to output actuation signals to automated electrochemical testing equipment so as to cause physical validation testing to be performed on the formulated electrolyte samples.

In some embodiments, feedback processing may be performed among the foregoing modules, although such feedback paths are not necessarily illustrated in FIG. 6. For example, the model evaluation module 260 may provide model-evaluation-related data to the model training module 250 so that model parameters, training settings, or both may be adjusted according to evaluation results. In addition, the interpretability analysis module 270 may provide interpretability-related data to the feature engineering module 240 so that feature screening, feature prioritization, or descriptor retention may be refined according to feature contribution information. The candidate deployment and update module 294 may also provide downstream update-related data to one or more upstream modules, including the model training module 250 or the feature engineering module 240, so that subsequent prediction processing can be improved based on downstream technical results.

Through the foregoing arrangement, the redox potential prediction system 200 is configured not only to generate redox potential prediction results and interpretability-related results, but also to convert such results into downstream technical actions including candidate screening, battery compatibility determination, design-guidance generation, and candidate deployment processing. Accordingly, the redox potential prediction system 200 provides an extended technical workflow for rechargeable lithium-ion battery development, rather than merely providing abstract analytical output.

The foregoing redox potential prediction systems 100 and 200 are configured to receive candidate electrolyte components, molecular structure information, first-principles-computation-related data, and feature data, and to perform lithium-ion-coordination-aware computation, feature processing, machine learning prediction, interpretability analysis, and candidate screening. Through such processing, the foregoing systems are capable of providing oxidation potential prediction results, reduction potential prediction results, interpretability-related results, and retained candidate sets for subsequent electrolyte formulation, validation, or battery-development processing in rechargeable lithium-ion batteries.

The foregoing processing is not practically achievable by human mental activity or by paper-and-pencil evaluation alone, because the foregoing systems process heterogeneous computational data, multidimensional feature descriptors, repeated model-training and evaluation results, and contribution-analysis results in an integrated computational workflow. Compared with conventional approaches that either rely on experimental electrochemical testing alone or use isolated molecular Quantum Mechanical (QM) calculations without coordinated machine-learning-based screening, the foregoing systems are capable of processing lithium-ion-coordination-aware computational data together with screened molecular descriptors to provide prediction results and downstream candidate-selection results for rechargeable lithium-ion battery development. Accordingly, the foregoing processing does not constitute mere mental analysis.

The present invention provides a lithium-ion-coordination-aware prediction framework in which high-throughput DFT, feature engineering, machine learning, and interpretability analysis are cooperatively used to predict redox potentials of electrolyte molecules. By constructing a database from both Lit-coordinated and non-Lit-coordinated computational states, the present invention enables extraction of coordination-sensitive descriptors for subsequent model training and screening. The present invention further provides interpretable prediction results indicating that oxidation potential is more strongly associated with electronic features, whereas reduction potential is more strongly associated with structural motifs such as C═O-related descriptors. Accordingly, the present invention supports efficient screening and development of electrolyte candidates for rechargeable lithium-ion batteries, particularly for applications involving wide electrochemical windows and high-voltage cathodes.

The functional units and modules of the apparatuses, systems, and/or methods in accordance with the embodiments disclosed herein may be implemented using computing devices, computer processors, or electronic circuitries including but not limited to application specific integrated circuits (ASIC), field programmable gate arrays (FPGA), microcontrollers, and other programmable logic devices configured or programmed according to the teachings of the present disclosure. Computer instructions or software codes running in the computing devices, computer processors, or programmable logic devices can readily be prepared by practitioners skilled in the software or electronic art based on the teachings of the present disclosure.

All or portions of the methods in accordance with the embodiments may be executed in one or more computing devices including server computers, personal computers, laptop computers, and mobile computing devices such as smartphones and tablet computers.

The embodiments may include computer storage media, transient and non-transient memory devices having computer instructions or software codes stored therein, which can be used to program or configure the computing devices, computer processors, or electronic circuitries to perform any of the processes of the present invention. The storage media, transient and non-transient memory devices can include, but are not limited to, floppy disks, optical discs, Blu-ray Disc, DVD, CD-ROMs, and magneto-optical disks, ROMs, RAMs, flash memory devices, or any type of media or devices suitable for storing instructions, codes, and/or data.

Each of the functional units and modules in accordance with various embodiments also may be implemented in distributed computing environments and/or cloud computing environments, wherein the whole or portions of machine instructions are executed in distributed fashion by one or more processing devices interconnected by a communication network, such as an intranet, Wide Area Network (WAN), Local Area Network (LAN), the Internet, and other forms of data transmission medium.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments were chosen and described in order to best explain the principles of the invention and its practical application, thereby enabling others skilled in the art to understand the invention for various embodiments and with various modifications that are suited to the particular use contemplated.

What is claimed is:

1. A redox potential prediction system for evaluating and screening candidate electrolyte molecules under a lithium-ion-coordinated condition and under a non-lithium-ion-coordinated condition for rechargeable lithium-ion batteries, comprising:
a candidate electrolyte collection module configured to collect candidate electrolyte molecules for subsequent redox potential prediction processing;
a first-principles computation module configured to receive the candidate electrolyte molecules and to perform first-principles computation on the candidate electrolyte molecules under a lithium-ion-coordinated condition and under a non-lithium-ion-coordinated condition so as to generate redox potential related computational data;
a feature extraction module configured to receive the redox-potential-related computational data and to extract electronic features and structural features associated with the candidate electrolyte molecules;
a feature engineering module configured to receive the electronic features and the structural features and to generate a processed feature set for subsequent machine-learning-based prediction;
a model training module configured to receive the processed feature set, to construct one or more machine-learning-based prediction models for redox potential prediction of the candidate electrolyte molecules, and to generate trained-model-related data based on the one or more machine-learning-based prediction models;
a model evaluation module configured to receive the trained-model-related data, to evaluate prediction performance of the one or more machine-learning-based prediction models, and to generate model-evaluation-related data and prediction-related data;
an interpretability analysis module configured to receive the model-evaluation-related data, to determine how different molecular descriptors contribute to oxidation-potential-related prediction and reduction-potential-related prediction, and to generate interpretability-related data; and
a redox prediction output module configured to receive the prediction-related data and the interpretability-related data, and to output oxidation potential prediction results, reduction potential prediction results, or both, associated with the candidate electrolyte molecules.

2. The redox-potential prediction system of claim 1, wherein the candidate electrolyte collection module is configured to selectively construct a candidate set from among the candidate electrolyte molecules according to molecular diversity and battery-related applicability.

3. The redox potential prediction system of claim 1, wherein the first-principles computation module is configured to perform first-principles computation on each candidate electrolyte molecule under a lithium-ion-coordinated condition and under a non-lithium-ion-coordinated condition so as to generate thermodynamic-cycle-related computational data for oxidation-related processing and reduction-related processing.

4. The redox potential prediction system of claim 3, wherein the first-principles computation module is further configured to identify coordination-capable atomic sites of the candidate electrolyte molecules, including oxygen-containing sites, nitrogen-containing sites, sulfur-containing sites, or combinations thereof, to evaluate a plurality of candidate coordination configurations associated with lithium ions, and to retain, from among the plurality of candidate coordination configurations, a coordination configuration having the highest stability for subsequent computation.

5. The redox potential prediction system of claim 1, wherein the feature extraction module is configured to extract electronic features including highest occupied molecular orbital-related information, lowest unoccupied molecular orbital-related information, electron-affinity-related information, ionization-potential-related information, and lithium-binding-energy-related information from the redox-potential-related computational data, and to extract structural features including elemental-composition-related information, bond-type-related information, ring-structure-related information, functional-group-related information, number-of-functional-group-related information, cyclic-structure-presence-related information, or combinations thereof from simplified molecular input line entry system (SMILES) representations, molecular fingerprint encodings, or other molecular structure descriptions.

6. The redox potential prediction system of claim 1, wherein the feature engineering module is configured to evaluate correlation between different features, to calculate a Pearson correlation coefficient between pairs of features, and to screen the features such that retained descriptors have pairwise absolute Pearson correlation coefficients less than or equal to 0.9.

7. The redox potential prediction system of claim 1, wherein the model training module is configured to train a plurality of machine-learning-based prediction models including an extreme gradient boosting (XGB) model, a random forest regression (RFR) model, a gradient boosting regression (GBR) model, a support vector regression (SVR) model, a k-neighbor regression (KNR) model, and a multilayer perceptron (MLP) model.

8. The redox potential prediction system of claim 1, wherein the feature extraction module is configured to convert the redox-potential-related computational data generated by the first-principles computation module into structured feature-source data, and to extract the electronic features and the structural features from the structured feature-source data for output to the feature engineering module.

9. The redox potential prediction system of claim 1, wherein the feature engineering module is configured to preprocess and screen the electronic features and the structural features received from the feature extraction module so as to generate the processed feature set for output to the model training module.

10. The redox potential prediction system of claim 1, wherein the model evaluation module is configured to provide model-evaluation-related data to the model training module so that the model training module adjusts training settings, model parameters, or both according to evaluation results generated by the model evaluation module.

11. The redox potential prediction system of claim 1, wherein the interpretability analysis module is configured to provide interpretability-related data to the feature engineering module so that the feature engineering module refines feature screening, feature prioritization, or descriptor retention according to descriptor contribution information, and wherein the interpretability analysis module is further configured to provide the interpretability-related data to the redox prediction output module.

12. The redox potential prediction system of claim 1, further comprising:
an electrolyte screening module configured to screen candidate electrolyte molecules according to redox-potential-related criteria;
a battery compatibility and design guidance module configured to determine battery-related compatibility of screened candidate electrolyte molecules and to generate design-guidance-related information; and
a candidate deployment and update module configured to generate a recommended candidate set for subsequent electrolyte formulation, validation, or battery-development processing.

13. The redox potential prediction system of claim 12, wherein the electrolyte screening module is configured to receive results output by the redox prediction output module and to rank, retain, exclude, or classify candidate electrolyte molecules according to oxidation-potential-related characteristics, reduction-potential-related characteristics, wide-electrochemical-window suitability, or combinations thereof.

14. The redox potential prediction system of claim 13, wherein the battery compatibility and design guidance module is configured to receive screening-related data from the electrolyte screening module and to determine whether candidate electrolyte molecules retained by the electrolyte screening module are compatible with one or more battery-related operating conditions including compatibility with high-voltage cathodes, desired electrochemical stability windows, temperature-related requirements, safety-related requirements, or combinations thereof, and to generate design-guidance-related information based on descriptor contribution relationships identified by the interpretability analysis module.

15. The redox potential prediction system of claim 12, wherein the candidate deployment and update module is configured to receive screening-related data, compatibility-related data, design-guidance-related data, or combinations thereof, to generate a recommended candidate set for subsequent electrolyte formulation, validation, or battery-development processing, to convert the recommended candidate set into machine-executable control instructions for transmission to an automated material synthesis system, a robotic dispensing apparatus, or both, so that selected candidate electrolyte formulations are physically prepared as electrolyte samples, and to output actuation signals to automated electrochemical testing equipment so as to cause physical validation testing to be performed on the electrolyte samples.

16. A method for evaluating and screening candidate electrolyte molecules under lithium-ion-coordinated condition and under a non-lithium-ion-coordinated condition for rechargeable lithium-ion batteries, the method comprising:
collecting candidate electrolyte molecules for subsequent redox potential prediction processing;
performing first-principles computation on the candidate electrolyte molecules under a lithium-ion-coordinated condition and under a non-lithium-ion-coordinated condition so as to generate redox-potential-related computational data;
extracting electronic features and structural features associated with the candidate electrolyte molecules from the redox-potential-related computational data;
generating a processed feature set based on the electronic features and the structural features for subsequent machine-learning-based prediction;
constructing one or more machine-learning-based prediction models for redox potential prediction of the candidate electrolyte molecules based on the processed feature set;
evaluating prediction performance of the one or more machine-learning-based prediction models;
determining how different molecular descriptors contribute to oxidation-potential-related prediction and reduction-potential-related prediction; and
outputting oxidation-potential prediction results, reduction-potential prediction results, or both, associated with the candidate electrolyte molecules.

17. The method of claim 16, wherein performing the first-principles computation comprises performing first-principles computation on each candidate electrolyte molecule under the lithium-ion-coordinated condition and under a non-lithium-ion-coordinated condition so as to generate thermodynamic-cycle-related computational data for oxidation-related processing and reduction-related processing.

18. The method of claim 16, wherein extracting the electronic features and the structural features comprises extracting electronic features including highest occupied molecular orbital-related information, lowest unoccupied molecular orbital-related information, electron-affinity-related information, ionization-potential-related information, and lithium-binding-energy-related information from the redox-potential-related computational data, and extracting structural features from SMILES representations, molecular fingerprint encodings, or other molecular structure descriptions.

19. The method of claim 16, wherein generating the processed feature set comprises:
converting redox-potential-related computational data generated by performing the first-principles computation into structured feature-source data;
extracting electronic features and structural features from the structured feature-source data; and
preprocessing and screening the electronic features and the structural features so as to generate the processed feature set for subsequent model construction.

20. The method of claim 16, further comprising:
screening the candidate electrolyte molecules according to redox-potential-related criteria;
determining battery-related compatibility of screened candidate electrolyte molecules and generating design-guidance-related information; and
generating a recommended candidate set for subsequent electrolyte formulation, validation, or battery-development processing,
wherein generating the recommended candidate set comprises converting the recommended candidate set into machine-executable control instructions for transmission to an automated material synthesis system, a robotic dispensing apparatus, or both, so that selected candidate electrolyte formulations are physically prepared as electrolyte samples.
